(19) United States
(12) Patent Application Publication
(10) Pub. No.: US 2024/0081019 A1
(43) Pub. Date: Mar. 7, 2024

(54) INFORMATION PROCESSING APPARATUS, INFORMATION PROCESSING METHOD, AND STORAGE MEDIUM

(71) Applicant: Canon Kabushiki Kaisha, Tokyo (JP)

(72) Inventor: Etsuya TAKAMI, Kanagawa (JP)

(21) Appl. No.: 18/457,550

(22) Filed: Aug. 29, 2023

(30) Foreign Application Priority Data
Sep. 1, 2022 (JP) 2022-139346

(51) Int. Cl. H05K 7/20; H04N 23/52; H10N 10/10

(52) U.S. Cl. CPC H05K 7/20209; H04N 23/52; H05K 7/2039; H10N 10/10

(57) ABSTRACT

There is provided with an information processing apparatus comprising a computer executing instructions. A predicting unit predicts a heat generation amount of a control target, wherein a temperature of the control target is controlled by a heat absorbing action or a heat radiating action of a heat exchange unit including a heat absorption unit and a heat radiation unit. A control unit controls a temperature of the heat absorption unit or the heat radiation unit of the heat exchange unit based on the predicted heat generation amount so that the temperature of the heat absorption unit or the heat radiation unit becomes a predetermined value.

### BACKGROUND OF THE INVENTION

### Field of the Invention

The present invention relates to an information processing apparatus, an information processing method, and a storage medium.

### Description of the Related Art

In recent years, a heating/cooling system using a Peltier element (module) has been used. For example, considering that a network camera is used in various environments for 24 hours, the network camera may be cooled by a Peltier element.

The most common cause of failure of the Peltier element is fatigue due to heat cycles generated in a solder layer joining a thermoelectric element and an electrode and in the thermoelectric element itself in the vicinity of the joint. Since the Peltier element is used by generating a temperature difference (ΔT) between a heat absorption side (low temperature side) and a heat radiation side (high temperature side), thermal stress is inevitably generated. Thus, in the thermoelectric element or the joining portion of the Peltier element, cracks are generated due to fatigue caused by a heat cycle, whereby the crack surface is oxidized, the electric resistance of that portion is increased, and the temperature is raised. As a result, burnout or melting of the solder layer and the thermoelectric element may eventually lead to disconnection.

There is a technique for suppressing the probability of occurrence of failure due to fatigue caused by a heat cycle when using a Peltier element. Japanese Patent Laid-Open No. 2005-331230 discloses a technique for setting and controlling an output time with respect to an output level of an applied voltage so that a temperature difference Δ T between a heat generating surface and a heat absorbing surface of a Peltier element gradually changes.

### SUMMARY OF THE INVENTION

According to one embodiment of the present invention, an information processing apparatus comprises a computer executing instructions that, when executed by the computer, cause the computer to function as: a predicting unit configured to predict a heat generation amount of a control target, wherein a temperature of the control target is controlled by a heat absorbing action or a heat radiating action of a heat exchange unit including a heat absorption unit and a heat radiation unit; and a control unit configured to control a temperature of the heat absorption unit or the heat radiation unit of the heat exchange unit based on the predicted heat generation amount so that the temperature of the heat absorption unit or the heat radiation unit becomes a predetermined value.

According to another embodiment of the present invention, an information processing method, when executed by a computer comprising a processor and a memory, causes the computer to: predict a heat generation amount of a control target, wherein a temperature of the control target is controlled by a heat absorbing action or a heat radiating action of a heat exchange unit including a heat absorption unit and a heat radiation unit; and control a temperature of the heat absorption unit or the heat radiation unit of the heat exchange unit based on the predicted heat generation amount so that the temperature of the heat absorption unit or the heat radiation unit becomes a predetermined value.

According to yet another embodiment of the present invention, a non-transitory computer-readable storage medium stores a program which, when executed by a computer comprising a processor and a memory, causes the computer to: predict a heat generation amount of a control target, wherein a temperature of the control target is controlled by a heat absorbing action or a heat radiating action of a heat exchange unit including a heat absorption unit and a heat radiation unit; and control a temperature of the heat absorption unit or the heat radiation unit of the heat exchange unit based on the predicted heat generation amount so that the temperature of the heat absorption unit or the heat radiation unit becomes a predetermined value.

Further features of the present invention will become apparent from the following description of exemplary embodiments (with reference to the attached drawings).

### BRIEF DESCRIPTION OF THE DRAWINGS

FIG. 1 is a diagram illustrating an example of a configuration of an imaging device including an information processing apparatus according to a first embodiment.

FIG. 2 is a flowchart illustrating an example of a heating/cooling process according to the first embodiment.

FIG. 3 is a flowchart illustrating an example of a heating/cooling process according to a second embodiment.

FIG. 4 is a flowchart illustrating an example of a heating/cooling process according to a third embodiment.

FIG. 5 is a diagram for explaining heating/cooling control not by the information processing apparatus according to the first embodiment.

FIG. 6 is a diagram for explaining the heating/cooling control by the information processing apparatus according to the first embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the technique described in Japanese Patent Laid-Open No. 2005-331230, the temperature difference ΔT between the heat generating surface and the heat absorbing surface of the Peltier element varies, and for example, ΔT may be a relatively high value or ΔT may be 0 when cooling is not required. As a result, there is a problem that fatigue of the Peltier element due to the heat cycle occurs in accordance with such a variation in ΔT.

An embodiment of the present invention provides an information processing apparatus that further suppresses fatigue of a heat exchange unit due to a heat cycle.

The information processing apparatus according to the present embodiment predicts a heat generation amount for a temperature control target by a heat absorbing action or a heat radiating action of a heat exchange unit including a heat absorption side and a heat radiation side. Next, the information processing apparatus controls the temperature of the heat absorption side or the heat radiation side in accordance with the predicted heat generation amount. Here, in particular, the information processing apparatus can control the temperature on the heat absorption side or the heat radiation side such that the temperature on the heat absorption side or the heat radiation side of the heat exchange unit becomes a predetermined value on the basis of the predicted heat generation amount.

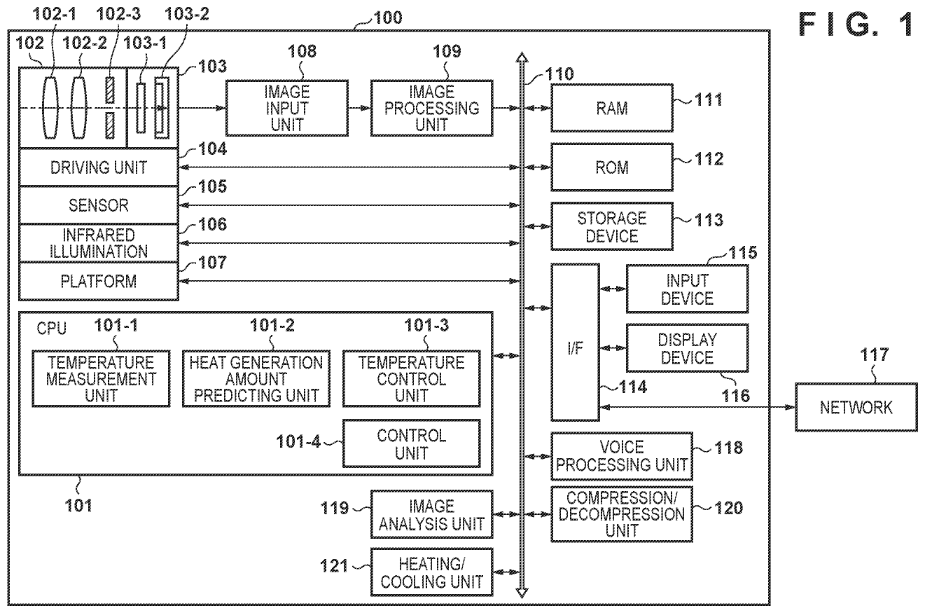

FIG. 1 is a block diagram illustrating an example of an imaging device 100 controlled by an information processing apparatus according to the present embodiment. The imaging device 100 according to the present embodiment includes an information processing apparatus 101, a RAM 111, a ROM 112, a storage device 113, an interface (I/F) 114, an input device 115, an output device 116, and a network 117. In addition, the imaging device 100 includes a lens 102, an imaging unit 103, a driving unit 104, a sensor 105, an infrared illumination 106, a platform 107, an image input unit 108, and an image processing unit 109 as functional units having an imaging function. Furthermore, the imaging device 100 may include a sound processing unit 118, an image analysis unit 119, a compression/decompression unit 120, and a heating/cooling unit 121 as other functional units. The functional units included in the imaging device 100 according to the present embodiment are communicably connected to each other via a bus 110 and can transmit and receive data to and from each other.

The imaging device 100 according to the present embodiment can be implemented as various devices having a function of imaging a moving image. The device having the function of imaging a moving image may be an imaging device such as a network camera, a video camera, a still camera, a drive recorder, or an in-vehicle camera, or may be a portable information terminal such as a mobile phone having an imaging function. In the present embodiment, the following description will be made assuming that the imaging device 100 is mounted on an imaging device such as a network camera.

The information processing apparatus 101 according to the present embodiment is assumed as a CPU mounted on the imaging device 100, but the information processing apparatus 101 may exist as an apparatus separate from the imaging device 100, such as a personal computer or a server which is an external apparatus of the imaging device 100. As described above, in a case where the information processing apparatus 101 and the imaging device 100 are separate apparatuses, a CPU of the imaging device 100 exists separately from the information processing apparatus 101, and such CPU executes each process by the imaging device 100.

In a heating/cooling system using a heat exchange unit, an information processing apparatus 101 maintains a temperature of a temperature control target within a predetermined range while suppressing variation in a temperature difference ΔT between a heat absorption side and a heat radiation side of the heat exchange unit in order to suppress fatigue of the heat exchange unit due to a heat cycle. For this purpose, the information processing apparatus 101 includes a temperature measurement unit 101-1, a heat generation amount predicting unit 101-2, a temperature control unit 101-3, and a control unit 101-4. Functional units of the information processing apparatus 101 will be described below.

The functional units 102 to 109 having the imaging function can perform normal imaging process according to a known technique, and will not be described in detail here. The lens 102 includes a zoom lens 102-1, a focus lens 102-2, and a diaphragm 102-3. The zoom lens 102-1 is a lens that changes the angle of view of the imaging device 100, and the focus lens 102-2 is a lens that adjusts the focus position of the imaging device 100. The zoom lens 102-1 and the focus lens 102-2 are moved along an optical axis of the imaging device 100 by the driving unit 104. The diaphragm 102-3 is a diaphragm that adjusts the amount of light passing through the lens 102. The diaphragm 102-3 is driven by the driving unit 104.

The imaging unit 103 includes an infrared cut filter 103-1 and an imaging element 103-2 configured by an image sensor or the like. The infrared cut filter 103-1 removes infrared light from light received by the imaging element 103-2. The infrared cut filter 103-1 is driven by the driving unit 104, and may be inserted when sufficient illuminance of a subject to be imaged is obtained even if the infrared cut filter 103-1 is inserted. Furthermore, the infrared cut filter 103-1 may be removed by the driving unit 104 when sufficient illuminance of a subject to be imaged cannot be obtained. When the infrared cut filter 103-1 is removed, the infrared illumination 106 may emit infrared light towards the subject to assist the visibility of the dark portion. Although details will be described later, the imaging element 103-2 is an element that converts received light into an electric signal, and the driving unit 104 can incline the posture with respect to the imaging optical axis plane orthogonal to the imaging optical axis system. The driving unit 104 can be controlled by the control unit 101-4.

The sensor 105 is a sensor consisting of any one or more of an acceleration sensor, an angular velocity sensor, a geomagnetic sensor, an illuminance sensor, and a temperature sensor, and acquires corresponding information. The sensor 105 can notify the acquired information, via the bus 110, to the information processing apparatus 101 or the like. Note that the sensor 105 according to the present embodiment includes a temperature sensor that measures a temperature of a temperature control target by the heat exchange unit, but may also include other sensors.

The platform 107 includes a pan driving unit and a tilt driving unit (not illustrated), and controls an imaging direction. The pan driving unit according to the present embodiment includes a bottom case and a turntable, and performs pan control of the imaging unit 103 by horizontally rotating the turntable. The pan driving unit according to the present embodiment can perform the pan control of the imaging unit 103 from −175 degrees to +175 degrees in the left-right direction from the initial posture. In addition, the tilt driving unit according to the present embodiment includes a turntable and a support column provided on the turntable and connected to the lens 102 and the imaging unit 103, and performs tilt control of the imaging unit 103 by vertically rotating the turntable. The tilt driving unit according to the present embodiment can perform the tilt control of the imaging unit 103 up to 90 degrees in the horizontal direction of 0 degrees and the straight upward direction which is the initial posture. As described above, the platform 107 can perform imaging while changing the imaging direction by rotating the lens and the imaging unit 103 in the horizontal direction or the hydraulic power direction.

The imaging element 103-2 photoelectrically converts light that has passed through the lens 102 and the infrared cut filter 103-1 into an electric signal. In the present embodiment, the imaging element 103-2 can convert an analog image signal input from the lens 102 into a digital image signal by known sampling process and amplification process such as correlated double sampling.

The image input unit 108 outputs the electric signal generated by the imaging element 103-2 to the image processing unit 109 as image data (digital image signal). The image processing unit 109 performs various types of image processing on the digital image signal input from the image input unit 108 and stores, via the bus 110, the processed digital image signal in the RAM 111. Here, the image processing unit 109 can perform various types of digital image processing on the digital image signal based on sensitivity information at the time of imaging the image signal, such as AGC (Automatic Gain Control) gain or ISO (International Organization for Standardization) sensitivity. The various types of digital image processing here may be, for example, optical black process, pixel defect correction process, aberration correction, peripheral light fall-off correction, gain process, white balance process, RGB interpolation process, dynamic range extension process, or color difference signal conversion. Furthermore, for example, the various types of digital image processing may be offset process, gamma correction process, noise reduction process, contour correction process, color tone correction process, light source type determination process, or scaling process.

The RAM 111 is a volatile memory such as an SRAM or a DRAM. The ROM 112 is a nonvolatile memory such as an EEPROM or a flash memory. The storage device 113 is a storage device such as a hard disk drive (HDD), a solid state drive (SSD), or an embedded multimedia card (eMMC).

A program for realizing each function by the information processing apparatus 101 and the imaging device 100 according to the present embodiment, and data used when the program is executed are stored in the ROM 112 or the storage device 113. Under the control of the information processing apparatus 101 (CPU), these programs and data are taken into the RAM 111 via the bus 110 and executed by the information processing apparatus 101.

The I/F 114 is various types of I/Fs related to input and output, and is connected to the input device 115 and the display device 116. The input device 115 is, for example, an operation key including a relay switch or a power switch, a cross key, a joystick, a touch panel, a keyboard, a pointing device, or the like, and acquires a user's input. The display device 116 is, for example, a display device such as an LCD display, and displays various types of information to be presented to the user, such as an image (e.g., that is temporarily stored in the RAM) or an operation menu. The I/F 114 is connected to a network 117 via a local area network (LAN) or the like. The connection with the network 117 may be either wired or wireless, and its form is not particularly limited.

The voice processing unit 118 is, for example, a speaker, and performs voice input/output process in the imaging device 100. The voice processing unit 118 according to the present embodiment can perform processing related to a voice function of outputting voice from a speaker. As the voice function, it is possible to adopt an arbitrary voice output function that is generally used.

The image analysis unit 119 performs image analyzing process including detection process according to a predetermined detection condition. The image analysis unit 119 can perform detection process by a known image analysis technology such as face detection, person detection, moving object detection, passage detection, congestion detection, trajectory detection, and desertion/carrying away detection. In addition, the image analysis unit 119 may use a graphics processing unit (GPU), a deep-learning processing unit (DLPU), or the like (not illustrated) included in the imaging device 100 for the analyzing process.

The compression/decompression unit 120 performs compression process and decompression process of an image. The compression/decompression unit 120 may generate compressed data by performing compression process of a predetermined format on the image, for example, and output the compressed data to the display device 116 or the network 117. Furthermore, the compression/decompression unit 120 can generate uncompressed data by performing decompression process of a predetermined format on the compressed data stored in the storage device 113. As a predetermined format used for the compression process and the decompression process, for example, a compression system compliant with the JPEG standard is performed on a still image, and a compression/decompression process compliant with MOTION-JPEG, MPEG2, AVC/H.264, AVC/H.265, or the like is performed on a moving image.

The heating/cooling unit 121 includes a heat exchange unit, a heat sink, a fan, a heater, and the like, and adjusts the temperature of a temperature control target (here, the imaging device 100). The heating/cooling unit 121 according to the present embodiment includes a Peltier element as a heat exchange unit, and can cool or radiate heat of the imaging device 100 by a heat absorbing action or a heat radiating action of the Peltier element. The Peltier element according to the present embodiment is a heat exchange unit including one surface (heat absorption side) that absorbs heat by flowing current in a predetermined direction and the other surface (heat radiation side) that radiates heat. The Peltier element switches functions between a heat absorption side and a heat radiation side by flowing current in a direction opposite to the predetermined direction. Hereinafter, a description will be made assuming that the heat exchange unit according to the present embodiment is a Peltier element.

Next, process performed by the information processing apparatus 101 will be described. The temperature measurement unit 101-1 acquires the measurement result of the temperature of the temperature control target by the Peltier element measured by the sensor 105. Here, the temperature control target is the imaging element 103-2, but is not particularly limited thereto as long as it is a component of the imaging device 100 whose temperature needs to be adjusted, and may be, for example, the driving unit 104 or the CPU of the imaging device 100. Hereinafter, such a temperature control target is referred to as a heating/cooling target.

The heat generation amount predicting unit 101-2 predicts a (future) heat generation amount of the heating/cooling target. For example, the heat generation amount predicting unit 101-2 may predict the heat generation amount according to the usage status of each function in the imaging device 100. Here, the heat generation amount predicting unit 101-2 can estimate the power consumption of each function by the imaging device 100 as the usage status of each function and predict the heat generation amount from the power consumption. The heat generation amount predicting unit 101-2 may estimate the power consumption for the function set by the user as having large power consumption among the functions in the imaging device 100. Here, it is assumed that the function whose power consumption is large is, for example, an infrared irradiation function by the infrared illumination 106, an audio function by the voice processing unit 118, a compression or decompression function by the compression/decompression unit 120, or a pan/tilt function by the driving of the platform 107. Hereinafter, when simply referred to as “heat generation amount”, it refers to the heat generation amount of the heating/cooling target described above.

Here, the heat generation amount predicting unit 101-2 predicts an averaged heat generation amount up to a predetermined timing (e.g., until the power is turned off after the imaging device 100 starts to operate) as a future heat generation amount, and temperature control is performed by the temperature control unit 101-3 based on the predicted heat generation amount. Here, the averaged heat generation amount may be, for example, an average value of heat generation amounts predicted for each unit period until a predetermined timing, may be an average value of heat generation amounts predicted for each event observed during a predetermined period, or may be calculated by other arbitrary conditional expressions. Note that the “event” here indicates one operation of a certain function of the imaging device 100 arbitrarily set by the user. As the event, for example, one operation (until the operation is interrupted for a predetermined period (e.g., 5 seconds) after the operation is started once) of the platform 107 may be set as one event, and the condition for setting the event as described above can be arbitrarily set by the user. Note that this event can be set for each function of the imaging device 100.

Note that, in the present embodiment, the description will be made assuming that “up to a predetermined timing” is a period from when the imaging device 100 starts operation to when the power is turned off as described above. However, this is not particularly limited as long as the temperature control of a period of an extent in which the fatigue due to the heat cycle of the imaging device 100 can be reduced can be performed. For example, a period from the start of the operation of the imaging device 100 to the elapse of a predetermined period (e.g., 30 minutes) may be set as the period of “until predetermined timing” described above.

The heat generation amount predicting unit 101-2 can estimate the power consumption of each of the functions described above based on data table prepared in advance. For example, the heat generation amount predicting unit 101-2 may have, in advance, information indicating the power consumption amount per operation time for each function, and calculate the power consumption from the operation time of each function. The power consumption amount with respect to the operation time of each function varies depending on the type of function, the operation setting, or the like, but can be set to an arbitrary value for each function by the user in advance. In addition, the heat generation amount predicting unit 101-2 has a data table indicating a correspondence relationship between the power consumption and the heat generation amount of each function in advance, and can predict the heat generation amount from the power consumption by referring to the data table.

For example, the heat generation amount predicting unit 101-2 can predict the heat generation amount based on the driving amount of the function of the imaging device 100. For example, the heat generation amount predicting unit 101-2 can predict the heat generation amount using the driving amount of the lens 102 as the driving amount of the function of the imaging device 100. Here, the driving amount of the lens 102 is a driving amount (angle or aperture value) or a driving time separately calculated for each of the zoom lens 102-1, the focus lens 102-2, and the diaphragm 102-3. In the present embodiment, the heat generation amount predicting unit 101-2 prepares in advance a data table indicating a correspondence relationship between the driving amount and the power consumption for each function, and can estimate the total power consumption by summing the power consumption estimated with reference to the data table for each function.

Here, as the driving amount of the function of the imaging device, a driving amount of the lens 102, a driving amount of the platform 107, an irradiation amount of infrared light by the infrared illumination 106, or the like can be used.

Furthermore, the heat generation amount predicting unit 101-2 may predict the heat generation amount according to a schedule such as, for example, the frequency of driving the lens 102. In this case, the heat generation amount predicting unit 101-2 can calculate an average power consumption amount for each event from the driving schedule of the lens 102 and predict the heat generation amount from the average power consumption amount. Here, the driving schedule of the lens 102 can be calculated separately for each of the zoom lens 102-1, the focus lens 102-2, and the diaphragm 102-3.

In addition, the heat generation amount predicting unit 101-2 may predict the heat generation amount in accordance with a schedule of controlling the posture of the imaging device 100, such as a frequency of driving the platform 107. In this case, the heat generation amount predicting unit 101-2 can calculate an average power consumption amount for each event from the driving schedule of the platform 107 and predict the heat generation amount from the average power consumption amount.

Furthermore, the heat generation amount predicting unit 101-2 may calculate the power consumption according to, for example, the usage status of an analysis function using the image analysis unit 119 or the CPU (information processing apparatus 101). Here, the usage status of the analysis function using the image analysis unit 119 or the CPU may be a usage time of the analysis function, or a usage time of a processor such as a GPU or a DLPU used for the analysis function may be taken into consideration.

Furthermore, the heat generation amount predicting unit 101-2 can acquire information indicating power consumption according to, for example, a status of a control process of inclining the posture of the imaging element 103-2 with respect to the imaging optical axis plane orthogonal to the imaging optical axis system by the driving unit 104. For example, the heat generation amount predicting unit 101-2 can calculate an average power consumption amount for each event from a schedule such as the frequency of inclining the imaging element, and predict the heat generation amount from the average power consumption amount. The event of the function in the driving unit 104 may be, for example, one event from the start of the control of inclining the posture of the imaging element 103-2 until the control is interrupted for a predetermined period (e.g., 5 seconds).

The heat generation amount predicting unit 101-2 may predict the heat generation amount from the power consumption of a plurality of functions or may predict the heat generation amount from the power consumption of a single function. When the heat generation amount is predicted from the power consumption of a plurality of functions, the heat generation amount predicting unit 101-2 may predict the heat generation amount from the sum of the power consumption, or may predict the heat generation amount with reference to a data table indicating a correspondence relationship between the power consumption and the heat generation amount for each function and sum the predicted heat generation amounts.

The temperature control unit 101-3 performs control so that the temperature on the heat absorption side or the heat generation side of the heat exchange unit (Peltier element) becomes a predetermined temperature according to the heat generation amount predicted by the heat generation amount predicting unit 101-2. Here, the temperature control unit 101-3 determines a designated value of the temperature difference ΔT between the heat absorption side and the heat generation side of the Peltier element based on the predicted heat generation amount, and controls the heating/cooling unit 121 so that the temperature difference ΔT falls within a predetermined range from the designated value.

In the present embodiment, the heat exchange unit included in the imaging device 100 is a Peltier element, and the designated value (second predetermined value) of the temperature difference ΔT described above is used as the temperature value specified when controlling the temperature of the Peltier element. However, if the temperature on the heat absorption side or the heat radiation side can be controlled in the same manner, such a process does not need to be performed. For example, the temperature on the heat absorption side or the heat radiation side may be directly specified instead of the temperature difference ΔT.

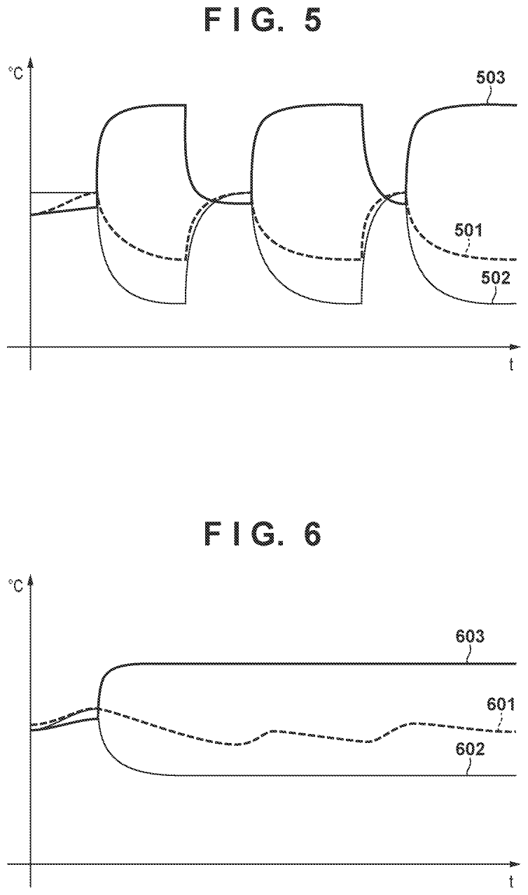

FIG. 5 is a diagram illustrating a variation example of the temperature 502 on the heat absorption side and the temperature 503 on the heat radiation side when the temperature control unit 101-3 does not control the temperature on the heat absorption side or the heat radiation side with respect to the temperature 501 of the heating/cooling target measured by the sensor 105. In this example, when the temperature 501 exceeds a predetermined threshold temperature due to the operation of the imaging device 100, the driving of the heating/cooling process by the Peltier element is started, and control is performed so that the temperature on the heat absorption side is low and the temperature on the heat radiation side is high. When the temperature of the heating/cooling target lowers due to the heat absorbing action on the heat absorption side and the temperature 501 falls below a predetermined threshold temperature, the driving of the heating/cooling process by the Peltier element is stopped and the temperature difference ΔT becomes 0 due to natural heat radiation. When the heating/cooling process is stopped, the temperature 501 increases due to the operation of the imaging device 100 and reaches the above-described threshold temperature again. Hereinafter, when such process is repeated, it is conceivable that occurrence of failure of the Peltier element is accelerated by fatigue due to the heat cycle.

In order to reduce the occurrence of failure of the Peltier element due to such a heat cycle, the information processing apparatus 101 according to the present embodiment predicts the heat generation amount of the heating/cooling target, and controls the temperature on the heat absorption side or the heat radiation side according to the predicted heat generation amount. Here, the temperature on the heat absorption side or the heat radiation side is set (controlled) to a predetermined value so that the temperature difference ΔT between the heat absorption side and the heat radiation side becomes a designated value (second predetermined value). Thus, the occurrence of fatigue due to the heat cycles can be reduced.

FIG. 6 is a diagram illustrating a variation example of the temperature 602 on the heat absorption side and the temperature 603 on the heat radiation side controlled by the temperature control unit 101-3 with respect to the temperature 601 of the heating/cooling target measured by the sensor 105. In the present embodiment, the heat generation amount predicting unit 101-2 predicts an average heat generation amount for a predetermined period (here, the entire period illustrated in FIG. 6), and the temperature control unit 101-3 determines the designated value of the temperature difference ΔT based on the heat generation amount. As described above, by setting the value of the temperature difference ΔT during the predetermined period to the designated value determined based on the predicted heat generation amount, it is possible to suppress fatigue due to the heat cycle of the Peltier element and reduce the occurrence of failure while performing desired heating/cooling.

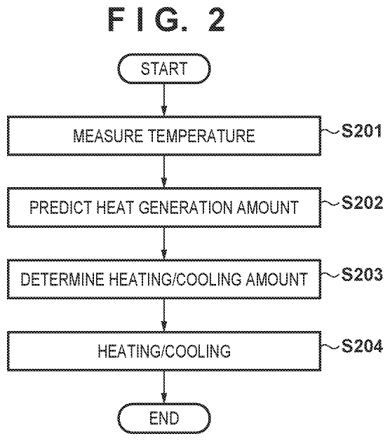

FIG. 2 is a flowchart illustrating an example of a heating/cooling processing using a Peltier element by the information processing apparatus 101 and the imaging device 100 according to the present embodiment. The process according to FIG. 2 is started when the operation of the imaging device 100 is started by the user.

In S201, the temperature measurement unit 101-1 acquires the temperature of the heating/cooling target measured by the sensor 105 through the bus 110. Note that, in the present embodiment, a plurality of sensors 105 are arranged in the imaging device 100, and the temperature measurement unit 101-1 acquires the temperature measured by each sensor 105, but the number of sensors 105 may be one. In S202, the heat generation amount predicting unit 101-2 predicts the heat generation amount of the heating/cooling target. In S203, the temperature control unit 101-3 determines a designated value of the temperature difference Δ T between the heat absorption side and the heat generation side of the Peltier element in accordance with the heat generation amount predicted in S202.

In S204, the temperature control unit 101-3 controls (sets) the current or the voltage for driving the Peltier element using PWM such that the temperature difference ΔT between the heat absorption side and the heat radiation side of the Peltier element becomes the designated value determined in S203.

According to such process, the heat generation amount of the heating/cooling target can be predicted, and the temperature of the heat exchange unit can be controlled (set) such that the temperature on the heat absorption side or the heat radiation side becomes a predetermined value according to the predicted heat generation amount.

Note that in the present embodiment, the description has been made assuming that the temperature control unit 101-3 determines the designated value of ΔT based on the average heat generation amount in the predetermined period. However, the heat generation amount used for the calculation of the future ΔT is not particularly limited in this manner, and for example, instead, a heat generation amount having the largest value among the heat generation amounts predicted by the heat generation amount predicting unit 101-2 in a predetermined period may be used.

### Second Embodiment

The information processing apparatus 101 according to a second embodiment predicts the heat generation amount of the heating/cooling target by processing similar to the processing in the first embodiment, and performs control such that the temperature on the heat absorption side or the heat generation side becomes a predetermined value according to the predicted heat generation amount. In addition, the information processing apparatus 101 according to the present embodiment updates the predetermined value of the temperature described above in accordance with a change in the temperature of the heating/cooling target with elapse of time. That is, the information processing apparatus 101 according to the present embodiment re-predicts the heat generation amount of the heating/cooling target according to elapse of time, and performs control such that the temperature on the heat absorption side or the heat generation side becomes a predetermined value based on the re-predicted heat generation amount.

The information processing apparatus 101 according to the present embodiment re-predicts the heat generation amount of the heating/cooling target and updates the predetermined value of the temperature described above in a case where a predetermined condition is satisfied while controlling the temperature on the heat absorption side or the heat generation side to be a predetermined value. Here, for example, the information processing apparatus 101 can set a case where the temperature of the heating/cooling target has changed by greater than or equal to a predetermined threshold from the time when the predetermined value of the temperature described above is set as a case where the predetermined condition is satisfied. The information processing apparatus 101 according to the present embodiment can acquire a measured temperature of the heating/cooling target at a predetermined time interval (e.g., 30 seconds) set in advance and determine whether or not the predetermined condition is satisfied. When the predetermined condition is satisfied, the heat generation amount of the heating/cooling target is predicted again at that time point, and the temperature on the heat absorption side or the heat generation side is controlled so that the temperature on the heat absorption side or the heat generation side becomes a predetermined value based on the predicted heat generation amount.

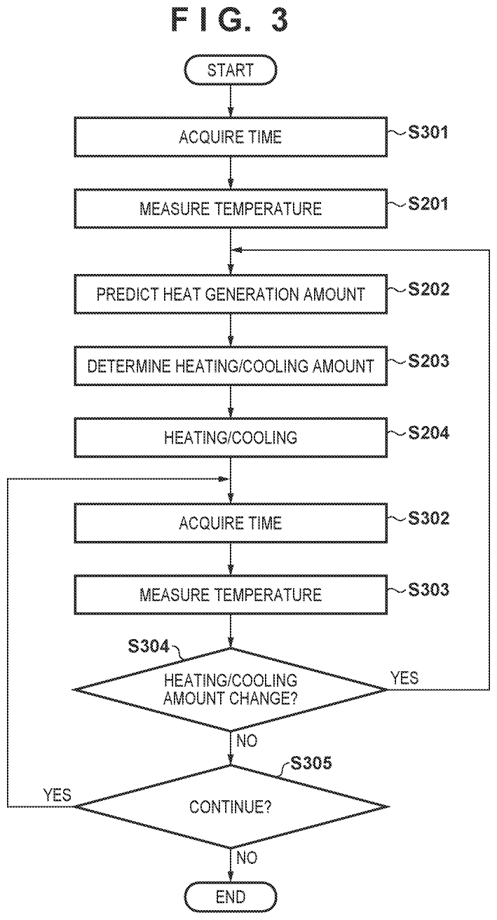

Hereinafter, the heating/cooling process by the information processing apparatus 101 and the imaging device 100 according to the second embodiment will be described with reference to FIG. 3. The process according to FIG. 3 includes S301 preceding S201 and S302 to S305 following S204, in addition to the process described with reference to FIG. 2.

In S301, the information processing apparatus 101 acquires the current time. Here, the information processing apparatus 101 can acquire the time managed by the OS (operation system) of the CPU. The time can be managed using, for example, a real time clock module (RTC) or the like. Since S201 to S204 following S301 are similar to the process according to the first embodiment, redundant description will be omitted. When S204 is ended, the process proceeds to S302.

In S302, the information processing apparatus 101 acquires the current time. Here, the information processing apparatus 101 acquires the current time by process similar to that in S301. In S303, the temperature measurement unit 101-1 acquires the temperature of the heating/cooling target measured by the sensor 105 through the bus 110. The process related to S303 can be performed similarly to S201, and the detailed description thereof will not be made here. It is assumed that the process related to S303 is performed at a timing when a predetermined time interval has elapsed from the time measured in S301.

In S304, the information processing apparatus 101 compares the temperature acquired in S201 with the temperature acquired in S303, and determines whether or not the difference is greater than or equal to a predetermined threshold. In a case where the difference is greater than or equal to the predetermined threshold, the process proceeds to S305, and otherwise, the process returns to S202.

In S305, the information processing apparatus 101 performs process similar to S202 to S204 (drives the Peltier element), and determines whether or not to continue the heating/cooling process according to FIG. 3. For example, in a case where a predetermined time (can be arbitrarily set) has elapsed from the time measured in S301, the information processing apparatus 101 may determine to end (not continue) the heating/cooling process according to FIG. 3. In a case where the heating/cooling process is continued, the process returns to S302, otherwise the process ends.

According to such process, when the temperature of the heating/cooling target changes by greater than or equal to the predetermined threshold, the future heat generation amount of the heating/cooling target is predicted again, and the designated value of ΔT can be determined again based on the predicted heat generation amount. Therefore, for example, it is possible to suppress the occurrence of overheating or overcooling due to a change in the outside air temperature (e.g., of day and night) with elapse of time.

Note that considering that overheating or overcooling may occur due to a change in the outside air temperature, the heat generation amount predicting unit 101-2 may re-predict the future heat generation amount of the heating/cooling target according to time (e.g., at the timing when day and night are switched). In this case, the time at which the re-prediction is performed can be arbitrarily set, but for example, the heat generation amount predicting unit 101-2 may re-predict the future heat generation amount of the heating/cooling target at the timing of 10:00 AM and the timing of 6:00 PM.

### Third Embodiment

In the first embodiment, the heat generation amount of the heating/cooling target is predicted, and the temperature on the heat absorption side or the heat generation side is controlled so that the temperature on the heat absorption side or the heat generation side becomes a predetermined value based on the predicted heat generation amount. However, there may be a case where the actual heat generation amount of the heating/cooling target becomes larger than the predicted value, and the temperature cannot be appropriately controlled. From such a viewpoint, the information processing apparatus 101 according to the third embodiment updates the predetermined value of the temperature described above in a case where the heat generation amount of the heating/cooling target is larger than the predicted value. That is, the information processing apparatus 101 according to the present embodiment further acquires information indicating the heat generation amount of the heating/cooling target, and re-predicts the heat generation amount when the acquired heat generation amount exceeds the predicted heat generation amount.

As described above, the information processing apparatus 101 according to the present embodiment determines whether or not the heat generation amount of the heating/cooling target is larger than the predicted value. In the present embodiment, the information processing apparatus 101 calculates an expected temperature of the heating/cooling target from the predicted heat generation amount. Next, description will be made assuming that the information processing apparatus 101 determines whether or not the difference between the calculated temperature and the temperature measured by the sensor 105 is larger than a predetermined threshold value (that is, the measured temperature of the heating/cooling target is treated as information indicating the heat generation amount of the heating/cooling target). Note that the process does not need to be limited to this as long as the predicted heat generation amount and the data corresponding to the actual heat generation amount can be compared with each other, and for example, whether the difference between the predicted heat generation amount and the heat generation amount calculated from the amount of change in the temperature of the heating/cooling target is larger than a threshold value may be determined.

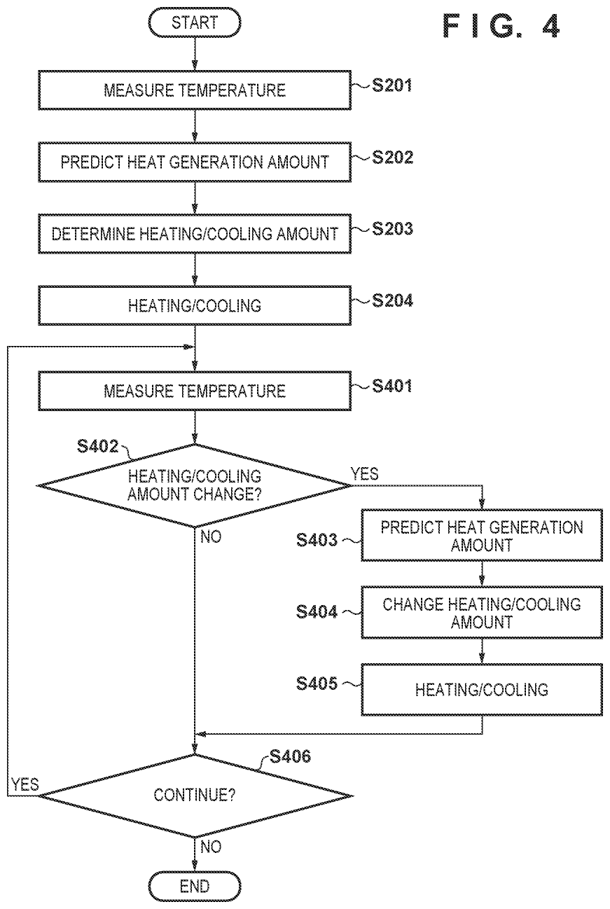

Hereinafter, the heating/cooling process by the information processing apparatus 101 and the imaging device 100 according to the third embodiment will be described with reference to FIG. 4. The process according to FIG. 4 includes S401 to S406 following S204 in addition to the process described with reference to FIG. 2.

In S401 following S204, the temperature measurement unit 101-1 acquires the temperature of the heating/cooling target measured by the sensor 105 via the bus 110. Here, the temperature measurement unit 101-1 acquires the temperature of the over-heating/cooling target by the same process as in S201.

In step S402, the information processing apparatus 101 determines whether or not the temperature of the heating/cooling target acquired in step S401 is higher than the temperature based on the heat generation amount predicted in step S402. When higher than the temperature based on the heat generation amount predicted in S402, the process proceeds to S403, otherwise, the process proceeds to S406.

in S403, the heat generation amount predicting unit 101-2 predicts the heat generation amount of the heating/cooling target. In S404, the information processing apparatus 101 newly determines (updates) the designated value of ΔT based on the heat generation amount predicted in S403. In S405, the temperature control unit 101-3 controls the current or the voltage for driving the Peltier element using PWM such that the temperature difference ΔT between the heat absorption side and the heat radiation side of the Peltier element becomes the value determined in S403. The process related to S403 to S405 can be performed in the same manner as S202 to S204. When S405 is ended, the process proceeds to S406.

In S406, the information processing apparatus 101 determines whether or not to continue the heating/cooling process according to FIG. 4. The information processing apparatus 101 may determine to end (not to continue) the heating/cooling process according to FIG. 4, for example, when the operation of the imaging device 100 is terminated in response to a user input (such as when the power is turned off). In a case where the heating/cooling process is continued, the process returns to S401, otherwise the process is ended.

Note that the temperature control unit 101-3 according to the present embodiment updates the designated value of ΔT based on the heat generation amount re-predicted by the heat generation amount predicting unit 101-2, but it is also conceivable that the temperature of the Peltier element is greatly changed by this update and fatigue may be induced. From such a viewpoint, the temperature control unit 101-3 can also set a range of ΔT based on the designated value and update the designated value of ΔT within the set range when the heat generation amount is re-predicted. Here, for example, a range of ±15° C. is set from the designated value of ΔT, and when the designated value of ΔT determined based on the re-predicted heat generation amount exceeds the upper limit (or lower limit) of the set range, the value of the upper limit (or lower limit) can be updated as the designated value. The range used here may be arbitrarily set by a user in consideration of suppression of fatigue of the Peltier element.

According to such process, when the heating/cooling target generates heat more intensely than predicted, it is possible to detect the heat generation and control the temperature of the heat exchange unit so as to obtain a more suitable temperature. In addition, by updating the designated value of ΔT within a predetermined change amount, it is possible to control the temperature of the heat exchange unit within a range in which fatigue can be suppressed by the heat cycle while coping with heat generation more intense than the prediction of the heating/cooling target.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-139346, filed Sep. 1, 2022, which is hereby incorporated by reference herein in its entirety.

What is claimed is:

1. An information processing apparatus comprising a computer executing instructions that, when executed by the computer, cause the computer to function as:
a predicting unit configured to predict a heat generation amount of a control target, wherein a temperature of the control target is controlled by a heat absorbing action or a heat radiating action of a heat exchange unit including a heat absorption unit and a heat radiation unit; and
a control unit configured to control a temperature of the heat absorption unit or the heat radiation unit of the heat exchange unit based on the predicted heat generation amount so that the temperature of the heat absorption unit or the heat radiation unit becomes a predetermined value.

2. The information processing apparatus according to claim 1, wherein the control unit controls the temperature of the heat absorption unit or the heat radiation unit of the heat exchange unit based on the predicted heat generation amount so that a difference in temperature between the heat absorption unit and the heat radiation unit becomes a second predetermined value.

3. The information processing apparatus according to claim 2, wherein the heat exchange unit is a Peltier element incorporated in an imaging device.

4. The information processing apparatus according to claim 3, further comprising an estimating unit configured to estimate power consumption by the imaging device; wherein
the predicting unit predicts the heat generation amount based on the estimated power consumption.

5. The information processing apparatus according to claim 4, wherein the estimating unit estimates the power consumption based on a driving amount of a lens of the imaging device.

6. The information processing apparatus according to claim 4, wherein the estimating unit estimates the power consumption based on a schedule for controlling a posture of the imaging device.

7. The information processing apparatus according to claim 4, wherein the estimating unit estimates the power consumption in accordance with a status of control process for tilting a posture of an imaging element of the imaging device.

8. The information processing apparatus according to claim 4, further comprising an analysis unit configured to perform an analyzing process of an image by the imaging device; wherein
the estimating unit estimates the power consumption according to a usage status of an analysis function by the analysis unit.

9. The information processing apparatus according to claim 1, further comprising a detection unit configured to detect, while the temperature of the heat absorption unit or the heat radiation unit is being controlled by the control unit,
that the temperature of a control target satisfies a predetermined condition; wherein
the predicting unit re-predicts the heat generation amount when detected that the predetermined condition is satisfied.

10. The information processing apparatus according to claim 9, wherein the detection unit detects that the temperature satisfies the predetermined condition when the temperature of the control target changes by greater than or equal to a predetermined threshold value.

11. The information processing apparatus according to claim 1,
further comprising an acquiring unit configured to acquire information indicating a heat generation amount of the control target; wherein the predicting unit re-predicts the heat generation amount when the heat generation amount indicated by the information exceeds the predicted heat generation amount.

12. The information processing apparatus according to claim 11, wherein the acquiring unit acquires information indicating the heat generation amount of the control target based on a measured value of the temperature of the control target.

13. An information processing method, when executed by a computer comprising a processor and a memory, causing the computer to:
predict a heat generation amount of a control target, wherein a temperature of the control target is controlled by a heat absorbing action or a heat radiating action of a heat exchange unit including a heat absorption unit and a heat radiation unit; and
control a temperature of the heat absorption unit or the heat radiation unit of the heat exchange unit based on the predicted heat generation amount so that the temperature of the heat absorption unit or the heat radiation unit becomes a predetermined value.

14. A non-transitory computer-readable storage medium storing a program which, when executed by a computer comprising a processor and a memory, causes the computer to:
predict a heat generation amount of a control target, wherein a temperature of the control target is controlled by a heat absorbing action or a heat radiating action of a heat exchange unit including a heat absorption unit and a heat radiation unit; and
control a temperature of the heat absorption unit or the heat radiation unit of the heat exchange unit based on the predicted heat generation amount so that the temperature of the heat absorption unit or the heat radiation unit becomes a predetermined value.
